(19) United States
(12) Patent Application Publication
(10) Pub. No.: US 2022/0293466 A1
(43) Pub. Date: Sep. 15, 2022

(54) Method for Forming Semiconductor Structure and Semiconductor Structure

(71) Applicant: CHANGXIN MEMORY TECHNOLOGIES, INC., Hefei City (CN)

(72) Inventors: Dongxue ZHANG, Hefei City (CN); Ge-Wei Lin, Hefei City (CN)

(21) Appl. No.: 17/452,460

(22) Filed: Oct. 27, 2021

Related U.S. Application Data
(63) Continuation of application No. PCT/CN2021/111446, filed on Aug. 9, 2021.

(30) Foreign Application Priority Data
Mar. 11, 2021 (CN) 202110264248.9

(51) Int. Cl. H01L 21/768; H01L 23/498; H01L 23/532

(52) U.S. Cl. CPC H01L 21/76846; H01L 23/49827; H01L 21/76802; H01L 23/53238

(57) ABSTRACT

The present disclosure relates to a field of semiconductor manufacturing technology, and in particular to a method for forming a semiconductor structure and a semiconductor structure. The method for forming the semiconductor structure includes: a substrate is placed in a reaction chamber, and the substrate includes at least one first conductive structure, a surface of the substrate is covered with an isolation layer, a surface of the isolation layer is covered with a first mask layer, and the first mask layer includes at least one etching window exposing the isolation layer; the isolation layer, a part of the substrate and a part of each of the at least one first conductive structure are etched along the at least one etching window according to preset etching parameters to form at least one trench; a barrier layer is formed; and at least one second conductive structure is formed.

### CROSS-REFERENCE TO RELATED APPLICATION

The present disclosure is a continuation of International Patent Application No. PCT/CN2021/111446, filed on Aug. 9, 2021, which claims priority to Chinese Patent Application No. 202110264248.9, filed on Mar. 11, 2021 and entitled “Method for Forming Semiconductor Structure and Semiconductor Structure”. The entireties of International Patent Application No. PCT/CN2021/111446 and Chinese Patent Application No. 202110264248.9 are incorporated herein by reference.

### TECHNICAL FIELD

The present disclosure relates to the field of semiconductor manufacturing technology, and in particular to a method for forming a semiconductor structure and a semiconductor structure.

### BACKGROUND

In the manufacturing process of a semiconductor structure, with the miniaturization of the size of an element and the narrowing of a line width, the spacing between adjacent wires is shortened; the condition for profiles etched by the damascene process is severe; and a micro loading effect easily causes copper ion migration in a subsequent process, thus causing short circuit between lines, causing an abnormal electric signal, and reducing the yield of elements.

Specifically, in the semiconductor damascene process, after a wire trench in formed by etching downwards, a barrier layer is usually deposited on the side walls of the trench, and then metal copper is filled in the trench to form a wire, such that the metal copper and a dielectric layer can be more tightly combined. However, due to the narrowing of the line width or the design of a circuit, too many by-products are generated on the side walls of a trench formed by the original process, and too many by-products tend to generate a deep micro loading effect on both sides of the bottom of the trench. In a subsequent process of forming the barrier layer, a cavity of the barrier layer is easily generated at the position of the micro loading effect, thus causing a copper ion migration phenomenon occurring to subsequently filled metal copper at the cavity, and finally causing short circuit between adjacent wires, thereby affecting the yield of semiconductor structures.

Therefore, how to avoid migration of metal ions in a damascene structure, thereby avoiding short circuit between adjacent wires and increasing the yield of semiconductor structures is a technical problem to be solved urgently at present.

### SUMMARY

According to some embodiments of the present disclosure, a method for forming a semiconductor structure is provided, the method for forming the semiconductor structure includes:

placing a substrate in a reaction chamber, wherein the substrate includes at least one first conductive structure, a surface of the substrate is covered with an isolation layer, a surface of the isolation layer is covered with a first mask layer, and the first mask layer includes at least one etching window exposing the isolation layer;

etching the isolation layer, a part of the substrate and a part of each of the at least one first conductive structure along the at least one etching window according to preset etching parameters to form at least one trench exposing the at least one first conductive structure, wherein the preset etching parameters enable etching rates at any two positions of a bottom of each of the at least one trench to be equal or enable an etching rate at a center of the bottom of each of the at least one trench to be greater than an etching rate at an edge of the bottom of each of the at least one trench, so that each of the at least one trench has a flat bottom surface or the bottom of each of the at least one trench is recessed towards the substrate;

forming a barrier layer covering an inner wall of each of the at least one trench; and

forming at least one second conductive structure that fills each of the at least one trench and covers a surface of the barrier layer.

According to some other embodiments of the present disclosure, a semiconductor structure is provided, the semiconductor structure includes:

a substrate, including at least one first conductive structure;

an isolation layer, covering a surface of the substrate;

at least one trench, penetrating through the isolation layer and extending to an inside of the substrate, wherein a bottom of each of the at least one trench exposes the at least one first conductive structure, and each of the at least one trench has a flat bottom surface or the bottom of each of the at least one trench is recessed towards the substrate;

a barrier layer, covering an inner wall of the at least one trench; and

at least one second conductive structure, filling the at least one trench and covering a surface of the barrier layer.

### BRIEF DESCRIPTION OF THE DRAWINGS

FIG. 1 is a flowchart of a method for forming a semiconductor structure according to specific embodiments of the present disclosure; and

FIGS. 2A-2H are schematic cross-sectional diagrams of a main process during formation of a semiconductor structure according to specific embodiments of the present disclosure.

### DETAILED DESCRIPTION OF THE EMBODIMENTS

Specific embodiments of a method for forming a semiconductor structure and a semiconductor structure provided in the present disclosure will be described in detail as below with reference to the accompanying drawings.

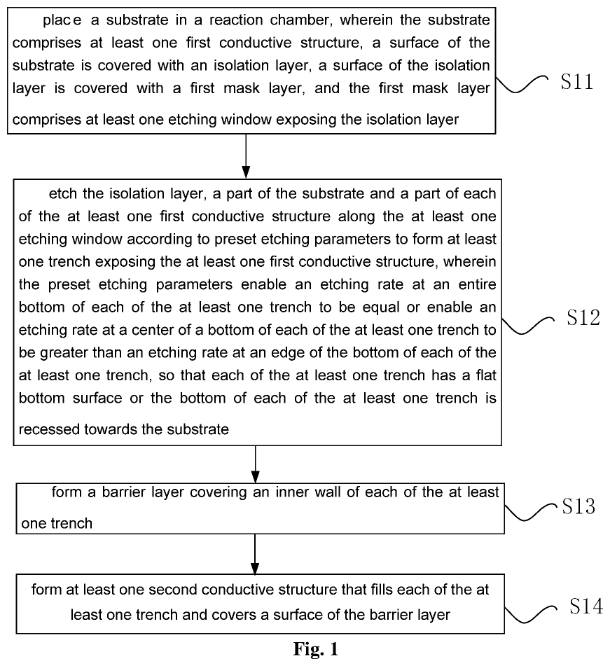

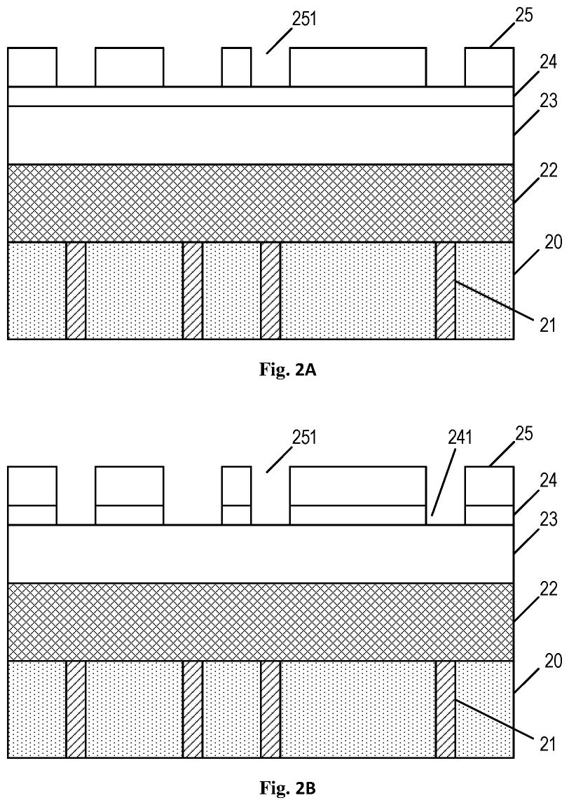

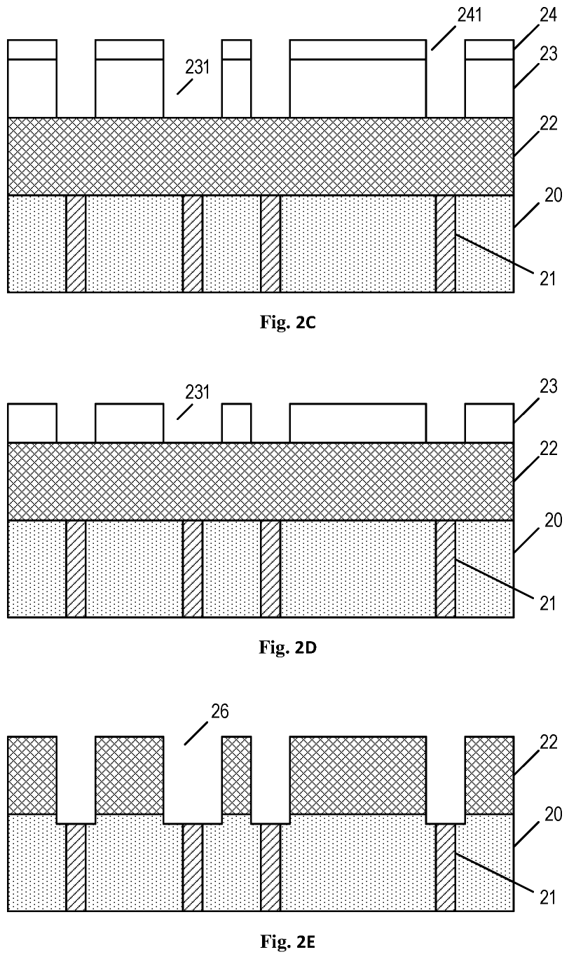

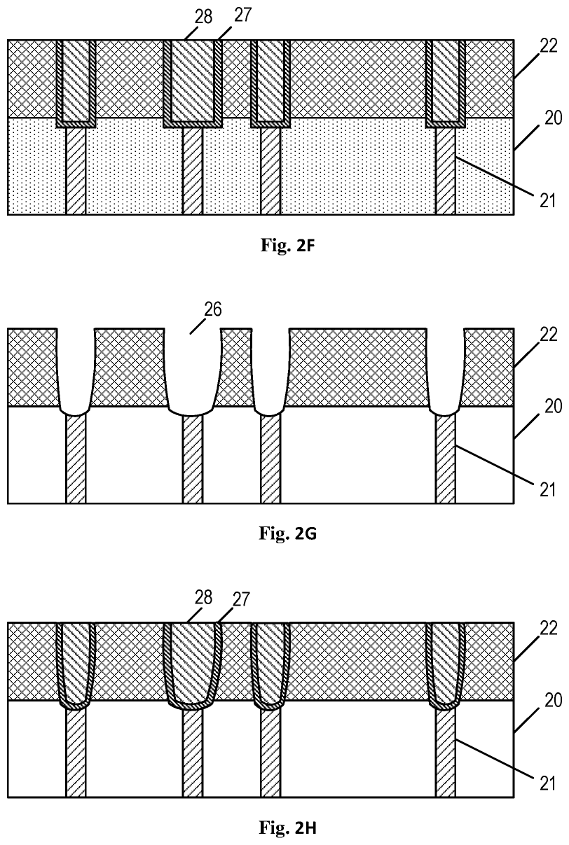

The present specific embodiments provide a method for forming a semiconductor structure. FIG. 1 is a flowchart of a method for forming a semiconductor structure according to the specific embodiments of the present disclosure. FIGS. 2A-2H are schematic cross-sectional diagrams of a main process during formation of a semiconductor structure according to specific embodiments of the present disclosure. As shown in FIGS. 1 and 2A-2H, the method for forming the semiconductor structure provided in the present specific embodiments includes the following steps:

step S11, a substrate 20 is placed in a reaction chamber, and the substrate 20 includes at least one first conductive structure 21, a surface of the substrate 20 is covered with an isolation layer 22, a surface of the isolation layer 22 is covered with a first mask layer 23, and the first mask layer 23 includes at least one etching window 231 exposing the isolation layer 22, as shown in FIG. 2D.

Specifically, in some embodiments, the substrate is a single-layer substrate, and in some other embodiments, the substrate is a multi-layer substrate formed by stacking a plurality of semiconductor layers. The substrate 20 may be, but is not limited to, a silicon substrate, and the present specific embodiments are described by taking a case where the substrate 20 is an oxide substrate as an example. In other examples, the substrate 10 is a semiconductor substrate such as gallium nitride, gallium arsenide, gallium carbide, silicon carbide, or SOI. In some embodiments, the substrate 20 includes only one first conductive structure 21; in some other embodiments, the substrate 20 includes a plurality of first conductive structures 21, and the plurality of first conductive structures 21 can be arranged in an array. In the present specific embodiments, each of the at least one first conductive structure 21 extends inside the substrate 20 in a direction perpendicular to the substrate 20, and a top surface of each of the at least one first conductive structure 21 is exposed to a surface of the substrate 20 and is used for being electrically connected to a subsequently formed second conductive structure. In some embodiments, a material of each of the at least one first conductive structure 21 is a metal material, e.g., tungsten, and in some other embodiments is a non-metal conductive material.

In the present specific embodiments, in order to further ensure the morphology of a subsequently formed trench, the specific step of forming the at least one etching window 231 exposing the isolation layer 22 in the first mask layer 23 includes: after the isolation layer 22 covering the substrate 20 is formed, the first mask layer 23 covering the surface of the isolation layer 22 and a second mask layer 24 covering a surface of the first mask layer 23 are formed. The first mask layer 23 can be an organic mask layer, e.g., an SOC (Spin On Carbon) layer; and the second mask layer 24 can be a hard mask layer, e.g., a BARC (Bottom Anti-Reflective Layer). Next, a patterned photoresist layer 25 is formed on a surface of the second mask layer 24, and at least one first opening 251 exposing the second mask layer 24 is provided in the photoresist layer 25, as shown in FIG. 2A. Then, the second mask layer 24 is etched along the at least one first opening 251 by using a mixed gas of a fluorocarbon-based gas and an argon gas (e.g., a mixed gas of CF₄, CHF₃ and Ar), and at least one second opening 241 exposing the first mask layer 23 is formed in the second mask layer 24, as shown in FIG. 2B. In the process of etching the second mask layer 24, a volume ratio of CF₄ to CHF₃ helps to control a feature size of the second opening 241.

Then, the first mask layer 23 is etched along the at least one second opening 241 to form the at least one etching window 231 in the first mask layer 23. In the present specific embodiments, an etching of the first mask layer 23 is performed in two steps: in a first step, the pattern of each of the at least one second opening 241 is quickly transferred to the first mask layer 23, and in this step, the first mask layer 23 is etched mainly using O₂, an etching rate is fast, and a surface roughness of a etched first mask layer 23 is relatively large, a formed structure is shown in FIG. 2C; and in a second step, a morphology of the first mask layer 23 after etching in the first step is repaired, and in this step, the first mask layer 23 is etched mainly using at least one kind of gas with slow etching rate, such as N₂ and/or H₂, and at this time, it can be ensured that a bottom of each of the at least one etching window 231 in the first mask layer 23 is fully opened, for example, the isolation layer 22 may be overetched, and it can also be ensured that side walls of each formed etching window 231 is smooth, a structure after etching is shown in FIG. 2D.

Step S12, the isolation layer 22, a part of the substrate 20 and a part of a part of each of the at least one first conductive structure 21 are etched along the at least one etching window 231 according to preset etching parameters to form at least one trench 26 exposing the at least one first conductive structure 21, and the preset etching parameters enable etching rates at any two positions of a bottom of each of the at least one trench 26 to be equal or enable an etching rate at a center of the bottom of each of the at least one trench 26 to be greater than an etching rate at an edge of the bottom of each of the at least one trench 26, so that each of the at least one trench 26 has a flat bottom surface or the bottom of each of the at least one trench 26 is recessed towards the substrate 20.

In some embodiments, a specific step of etching the isolation layer 22, the part of the substrate 20 and the part of each of the at least one first conductive structure 21 along the at least one etching window according to the preset etching parameters includes:

the isolation layer 22, the part of the substrate 20 and the part of each of the at least one first conductive structure 21 are etched along the at least one etching window 231 under a preset pressure in the reaction chamber, such that etching rates at any two positions of the bottom of each of the at least one trench are equal, as shown in FIG. 2E.

In some embodiments, the preset pressure is 40 mTorr to 60 mTorr.

In an embodiment, in a process of dry etching the isolation layer 22, a pressure in the reaction chamber is within a range of 40 mTorr to 60 mTorr, which means that the pressure in the reaction chamber increases, a concentration of plasmas for an etching reaction with the isolation layer 22 will increase, thus shortening a free path of ions, reducing a collision rate between ions, and improving a chemical reaction rate, thereby improving a micro loading effect in a etching process, such that in a process of etching to form the at least one trench 26, the etching rates at any two positions of the bottom of each of the at least one trench 26 are equal, and the substrate 20 and the at least one first conductive structure 21 can be overetched, so that each of the at least one trench 26 finally formed has a flat bottom surface, and a bottom surface of each of the at least one trench 26 is lower than the surface of the substrate 20, as shown in FIG. 2E.

In some embodiments, the specific step of etching the isolation layer 22, the part of the substrate 20 and the part of each of the at least one first conductive structure 21 along the at least one etching window according to the preset etching parameters includes:

the isolation layer 22, the part of the substrate 20 and the part of each of the at least one first conductive structure 21 are etched along the at least one etching window 231 under a condition that an auxiliary gas is transmitted to the reaction chamber at a preset flow rate, such that the etching rate at the center of the bottom of each of the at least one trench 26 is greater than the etching rate at an edge of the bottom of each of the at least one trench 26, the auxiliary gas is used for removing by-products generated by an etching reaction, as shown in FIG. 2G.

In some embodiments, a material of the isolation layer 22 is an oxide material, and the auxiliary gas is oxygen.

In some embodiments, a flow rate of the auxiliary gas is 12 sccm to 20 sccm.

In some embodiments, an etching gas is a gas containing a carbon element and a fluorine element.

In another embodiment, the material of the isolation layer 22 is an oxide material, the material of the substrate 20 is an oxide material, and a material of each of the at least one first conductive structure 21 is tungsten. In a process of etching the isolation layer 22 by using a dry etching process, the etching gas is a mixed gas of C₄F₆, O₂ and Ar, and C₄F₆ is used for etching reaction with the isolation layer 22, Ar is used for diluting C₄F₆ so as to control a reaction rate of the etching reaction, and O₂ is used as the auxiliary gas for removing by-products generated in a etching process. In this embodiment, when a micro loading effect occurs to a morphology of the bottom of the each of the at least one trench 26, a relative proportional relationship between components in the etching gas is adjusted, for example, increasing a flow rate of the auxiliary gas to enable the flow rate of the auxiliary gas to be 12 sccm to 20 sccm can reduce a deposition rate of by-products during etching, and thus reducing a deposition rate of the by-products on side walls of each of the at least one trench 26 can reduce an etching rate at an edge of the bottom of each of the at least one trench 26, thereby improving the micro loading effect.

Step S13, a barrier layer 27 covering an inner wall of micro loading effect 26 is formed.

Step S14, at least one second conductive structure 28 that fills micro loading effect 26 and covers a surface of the barrier layer 27 is formed.

In some embodiments, a specific step of forming the barrier layer 27 covering the inner wall of the barrier layer 27 includes:

a barrier material is deposited on the inner wall of each of the at least one trench 26 to form the barrier layer 27 covering an entire inner wall of each of the at least one trench 26.

Specifically, after forming each of the at least one trench 26 as shown in FIG. 2E or FIG. 2G, a barrier material (e.g., tantalum) is deposited on the inner wall of each of the at least one trench 26 to form the barrier layer 27. Due to the improvement of the micro loading effect, it can be ensured that the barrier layer 27 completely covers an entire inner wall of each of the at least one trench 26. Then, a conductive material such as copper is deposited in each of the at least one trench 26 to form the at least one second conductive structure 28 that fills the at least one trench 26 and covers the surface of the barrier layer 27, as shown in FIG. 2F or FIG. 2H. As the barrier layer 27 covers the entire inner wall of each of the at least one trench 26, migration of conductive particles (e.g., copper ions) in the at least one second conductive structure 28 subsequently formed can be effectively avoided, avoiding short circuit between adjacent second conductive structures 28, improving the performance of the semiconductor structure, and increasing the yield of the semiconductor structure.

In some embodiments, each of the at least one trench 26 has a width greater than or equal to 80 nm.

In some embodiments, the substrate 20 includes a plurality of first conductive structures 21; and a specific step of forming the at least one trench 26 exposing the at least one first conductive structure 21 further includes:

a plurality of trenches 26 are formed in one-to-one correspondence with the plurality of first conductive structures 21, and a distance between adjacent trenches 26 is less than or equal to 100 nm to 150 nm.

Specifically, when the width of each of the at least one trench 26 required to be formed is greater than or equal to 80 nm or the distance between the adjacent trenches 26 is less than or equal to 100 nm⋅to 150 nm, the micro loading effect tends to occur. Therefore, the method for forming the semiconductor structure provided in the present specific embodiments is particularly applicable to a case where the width of each of the at least one trench 26 required to be formed is greater than or equal to 80 nm or the distance between the adjacent trenches 26 is less than or equal to 100 nm⋅to 150 nm. Certainly, when the width of each of the at least one trench required to be formed is another width or the distance between the adjacent trenches is another values, the method provided in the present specific embodiments is also applicable.

In addition, when the barrier layer cannot be deposited at the bottom of each of the at least one trench or a width of the barrier layer deposited at an edge of the bottom of each of the at least one trench is less than 1 nm due to the micro loading effect, the method for forming the semiconductor structure provided in the present specific embodiments can also be used for formation.

In order to solve the described problem, present specific embodiments further provide a semiconductor structure. The semiconductor structure provided in the present specific embodiments can be formed by using the method shown in FIGS. 1 and 2A-2H. For the schematic diagrams of the semiconductor structure provided in the present specific embodiments, reference can be made to FIGS. 2G and 2H. As shown in FIGS. 2G and 2H, the semiconductor structure provided in the present specific embodiments includes:

a substrate 20, the substrate 20 includes at least one first conductive structure 21;

an isolation layer 22, covering a surface of the substrate 20;

at least one trench 26, penetrating through the isolation layer 22 and extending to an inside of the substrate 20, and a bottom of each of the at least one trench 26 exposes the at least one first conductive structure 21, and each of the at least one trench 26 has a flat bottom surface or the bottom of each of the at least one trench 26 is recessed towards the substrate 20;

a barrier layer 27, covering an inner wall of each of the at least one trench 26; and

at least one second conductive structure 28, filling the at least one trench 26 and covering a surface of the barrier layer 27.

In some embodiments, the barrier layer 27 covers an entire inner wall of each of the at least one trench 26.

In some embodiments, a material of the barrier layer 27 is tantalum; and

a material of each of the at least one second conductive structure 28 is copper.

In some embodiments, each of the at least one trench 26 has a width greater than or equal to 80 nm.

In some embodiments, the substrate 20 includes a plurality of first conductive structures 21; and the semiconductor structure further comprise a plurality of trenches 26,

the plurality of trenches 26 are in one-to-one correspondence with the plurality of first conductive structures 21, and a distance between adjacent trenches 26 is less than or equal to 100 nm⋅to 150 nm.

According to the method for forming the semiconductor structure and the semiconductor structure provided in the present specific embodiments, the etching parameters are controlled in the process of etching the isolation layer to form the at least one trench, such that the etching rates at any two positions of the bottom of each of the at least one trench are equal or the etching rate at the center of the bottom of each of the at least one trench is greater than the etching rate at the edge of the bottom of each of the at least one trench, thereby ensuring that each of the at least one trench has a flat bottom surface or the bottom of each of the at least one trench is recessed towards the substrate, reducing or even avoiding a micro loading effect, and avoiding the problem that conductive particle migration tends to occur after the second conductive structure is formed in each of the at least one trench, thus avoiding short circuit between adjacent second conductive structures, i.e. avoiding the problem that short circuit between adjacent wires tends to occur in a damascene structure, improving the electrical performance of the semiconductor structure, and increasing the yield of the semiconductor structure.

The descriptions above are merely preferred embodiments of the present disclosure. It should be noted that a person of ordinary skill in the art, without deviation from the principles of the present disclosure, may make further improvements or modifications. Such improvements and modifications shall be considered as falling within the scope of protection of the present disclosure

What is claimed is:

1. A method for forming a semiconductor structure, comprising:
placing a substrate in a reaction chamber, wherein the substrate comprises at least one first conductive structure, a surface of the substrate is covered with an isolation layer, a surface of the isolation layer is covered with a first mask layer, and the first mask layer comprises at least one etching window exposing the isolation layer;
etching the isolation layer, a part of the substrate and a part of each of the at least one first conductive structure along the at least one etching window according to preset etching parameters to form at least one trench exposing the at least one first conductive structure, wherein the preset etching parameters enable etching rates at any two positions of a bottom of each of the at least one trench to be equal or enable an etching rate at a center of the bottom of each of the at least one trench to be greater than an etching rate at an edge of the bottom of each of the at least one trench, so that each of the at least one trench has a flat bottom surface or the bottom of each of the at least one trench is recessed towards the substrate;
forming a barrier layer covering an inner wall of each of the at least one trench; and
forming at least one second conductive structure that fills each of the at least one trench and covers a surface of the barrier layer.

2. The method for forming the semiconductor structure according to claim 1, wherein etching the isolation layer, the part of the substrate and the part of each of the at least one first conductive structure along the at least one etching window according to the preset etching parameters comprises:
etching the isolation layer, the part of the substrate and the part of each of the at least one first conductive structure along the at least one etching window under a preset pressure in the reaction chamber, such that the etching rates at any two positions of the bottom of each of the at least one trench are equal.

3. The method for forming the semiconductor structure according to claim 2, wherein the preset pressure is 40 mTorr to 60 mTorr.

4. The method for forming the semiconductor structure according to claim 1, wherein etching the isolation layer, the part of the substrate and the part of each of the at least one first conductive structure along the at least one etching window according to the preset etching parameters comprises:
etching the isolation layer, the part of the substrate and the part of each of the at least one first conductive structure along the at least one etching window under a condition that an auxiliary gas is transmitted to the reaction chamber at a preset flow rate, such that the etching rate at the center of the bottom of each of the at least one trench is greater than the etching rate at the edge of the bottom of each of the at least one trench, the auxiliary gas being used for removing by-products generated by an etching reaction.

5. The method for forming the semiconductor structure according to claim 4, wherein a material of the isolation layer is an oxide material, and the auxiliary gas is oxygen.

6. The method for forming the semiconductor structure according to claim 5, wherein a flow rate of the auxiliary gas is 12 sccm to 20 sccm.

7. The method for forming the semiconductor structure according to claim 5, wherein an etching gas is a gas containing a carbon element and a fluorine element.

8. The method for forming the semiconductor structure according to claim 1, wherein each of the at least one trench has a width greater than or equal to 80 nm.

9. The method for forming the semiconductor structure according to claim 1, wherein the substrate comprises a plurality of first conductive structures; and forming the at least one trench exposing the at least one first conductive structure further comprises:
forming a plurality of trenches, the plurality of trenches being in one-to-one correspondence with the plurality of the first conductive structures, a distance between adjacent trenches being less than or equal to 100 nm to 150 nm.

10. The method for forming the semiconductor structure according to claim 1, wherein forming the barrier layer covering the inner wall of each of the at least one trench comprises:
depositing a barrier material on the inner wall of each of the at least one trench to form the barrier layer covering an entire inner wall of each of the at least one trench.

11. A semiconductor structure, comprising:
a substrate, comprising at least one first conductive structure;
an isolation layer, covering a surface of the substrate;
at least one trench, penetrating through the isolation layer and extending to an inside of the substrate, wherein a bottom of each of the at least one trench exposes the at least one first conductive structure, and each of the at least one trench has a flat bottom surface or the bottom of each of the at least one trench is recessed towards the substrate;
a barrier layer, covering an inner wall of the at least one trench; and
at least one second conductive structure, filling the at least one trench and covering a surface of the barrier layer.

12. The semiconductor structure according to claim 11, wherein the barrier layer covers an entire inner wall of the at least one trench.

13. The semiconductor structure according to claim 11, wherein a material of the barrier layer is tantalum; and
a material of each of the at least one second conductive structure is copper.

14. The semiconductor structure according to claim 11, wherein each of the at least one trench has a width greater than or equal to 80 nm.

15. The semiconductor structure according to claim 11, wherein the substrate comprises a plurality of first conductive structures; and the semiconductor structure further comprise a plurality of trenches,
the plurality of trenches are in one-to-one correspondence with the plurality of first conductive structures, a distance between adjacent trenches being less than or equal to 100 nm to 150 nm.

16. The method for forming the semiconductor structure according to claim 1, wherein etching the isolation layer, the part of the substrate and the part of each of the at least one first conductive structure along the at least one etching window according to the preset etching parameters comprises:
etching the isolation layer, the part of the substrate and the part of each of the at least one first conductive structure along the at least one etching window under a condition that an auxiliary gas is transmitted to the reaction chamber at a preset flow rate, such that the etching rate at the center of the bottom of each of the at least one trench is greater than the etching rate at the edge of the bottom of each of the at least one trench, the auxiliary gas being used for removing by-products generated by an etching reaction.
